(19) United States
(12) Patent Application Publication
(10) Pub. No.: US 2008/0179600 A1
(43) Pub. Date: Jul. 31, 2008

(54) THIN FILM TRANSISTOR, METHOD OF PRODUCING THE SAME, AND DISPLAY DEVICE USING THE THIN FILM TRANSISTOR

(75) Inventor: Toru TAKEGUCHI, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: MITSUBISHI ELECTRIC CORPORATION, Chiyoda-ku (JP)

(21) Appl. No.: 11/954,338

(22) Filed: Dec. 12, 2007

(30) Foreign Application Priority Data
Jan. 31, 2007 (JP) 2007-021364

(51) Int. Cl. H01L 29/10; H01L 21/00

(52) U.S. Cl. 257/72; 257/66; 438/151; 257/E21.001; 257/E29.043

(57) ABSTRACT

It is an object to obtain a display device which has a thin film transistor using a semiconductor film, and in which initial failures are reduced, and a high-resolution display due to miniaturization of the thin film transistor is enabled. In a thin film transistor, a gate electrode 6 is formed above a polycrystalline semiconductor film 4 via a gate insulating film 5. A taper angle θ2 of a section of a pattern end portion of the polycrystalline semiconductor film 4 in a region where the polycrystalline semiconductor film 4 and the gate electrode 6 intersect with each other is smaller than a taper angle θ1 of the other region.

### CROSS-REFERENCE TO RELATED APPLICATION

This application is based upon and claims the benefit of priority from Japanese Patent Application No. 2007-021364 filed on Jan. 31, 2007, the entire contents of which are incorporated herein by reference.

### BACKGROUND OF THE INVENTION

1. Field

The present invention relates to a thin film transistor, a method of producing it, and a display device using it.

2. Description of the Related Art

A liquid crystal display device (LCD) which is one of conventional usual thin panels is generally used as a monitor for a personal computer, that for portable information terminal, and the like, while taking advantage of low power consumption, small size, and lightweight. Recently, the liquid crystal display device (LCD) is widely used in a TV set, and will replace a conventional cathode-ray tube. In addition, an electroluminescence EL display device in which a luminous body such as an EL element is employed in a pixel display portion is used as a next-generation panel device. In such an EL element, problems of an LCD such as restrictions of view angle and contrast and difficulty of followability of high-speed response to a motion picture can be solved, and features which an LCD does not have, such as the self-luminous type, wide view angle, high contrast, and high-speed response are advantageously used.

Switching elements such as thin film transistors (TFT) are formed in a pixel region of such a display device. An example of frequently employed TFTs is a TFT having a MOS structure using a semiconductor film. As TFTs, there are several kinds including the inverse staggered type and the top-gate type. Semiconductor films include an amorphous semiconductor film and a polycrystalline semiconductor film. They are adequately selected in accordance with the use and performance of a display device. In a panel of a small size, it is often to use a polycrystalline semiconductor film which enables miniaturization of a TFT because the aperture ratio of a display region can be increased.

When a thin film transistor using a polycrystalline semiconductor film (LTPS-TFT) is used in formation of a circuit in the periphery of a display device, the numbers of ICs and substrates on which ICs are mounted can be reduced, and the periphery of the display device can be simplified. Therefore, a highly reliable display device having a narrow frame can be realized. In a liquid crystal display device, not only the capacity of a switching transistor for each pixel, but also the area of a holding capacity connected to the drain side can be reduced. Therefore, a liquid crystal display device of a high resolution and a high aperture ratio can be realized. In a high-resolution liquid crystal display device such as QVGA (pixel number: 240×320) or VGA (pixel number: 480×640) for a panel which is as small as that for a portable telephone, consequently, an LTPS-TFT plays a leading role. As described above, an LTPS-TFT is largely superior in performance than an amorphous silicon TFT, and its resolution is expected to be further advanced.

As a method of producing a polycrystalline semiconductor film that is to be used in an LTPS-TFT, known is a method in which an amorphous semiconductor film is first formed above a silicon oxide film or the like that is formed as a foundation film on a substrate, and thereafter the semiconductor film is irradiated with a laser beam to be formed as a polycrystalline film (for example, see Patent Reference 1). In addition, a method is known in which a TFT is produced after such a polycrystalline semiconductor film is formed. Specifically, a gate insulating film made of a silicon oxide film is first formed on a polycrystalline semiconductor film, and a gate electrode is formed. Thereafter, impurities such as phosphorus or boron are introduced into the polycrystalline semiconductor film via the gate insulating film, thereby forming source/drain regions. Then, an interlayer insulating film is formed so as to cover the gate electrode and the gate insulating film, and thereafter contact holes which reach the source/drain regions are opened in the interlayer insulating film and the gate insulating film. A metal film is formed on the interlayer insulating film, and patterned so that the metal film is connected to the source/drain regions formed on the polycrystalline semiconductor film, thereby forming source/drain electrodes. Thereafter, a pixel electrode or a self-luminous element is formed so as to be connected to the drain electrode, with the result that a TFT of the top-gate type is formed.

As an LTPS-TFT, a TFT of the top-gate type is usually employed. In such a TFT, as a gate insulating film, a silicon oxide film which is formed in a very thin thickness of about 100 nm is used to be sandwiched between a gate electrode and a polycrystalline semiconductor film, thereby forming a MOS structure. The silicon oxide film is sandwiched between a polycrystalline semiconductor film to which impurities are introduced to lower the resistance, and a conductive layer, so that the film is used also for forming a holding capacity. The small thinness of the silicon oxide film allows the area of the holding capacity to be reduced, thereby contributing to enhanced resolution.

The gate insulating film has a very small thickness. Consequently, there is a problem in that the dielectric strength of the gate insulating film is low particularly in an end portion of the polycrystalline semiconductor film which is formed below the gate insulating film. As a countermeasure against this problem, a technique is employed in which a pattern end portion of a semiconductor film is processed so as to have a tapered shape, thereby improving the covering property of a gate insulating film (for example, see Patent Reference 2). In the process of forming a tapered shape, the resist withdrawal method using a dry etching is sometimes used (for example, see Patent Reference 3). Furthermore, a technique in which different tapered shapes are formed with using the difference in the volumes of resists is known (for example, see Patent Reference 4).

[Patent Reference 1] JP-A-2003-17505 (FIG. 2)

[Patent Reference 2] JP-A-8-255915 (FIG. 2)

[Patent Reference 3] JP-A-2004-294805 (page 9)

[Patent Reference 4] JP-A-2006-128413 (FIG. 3c)

### SUMMARY OF THE INVENTION

In the process using the resist withdrawal method, all pattern end portions of a polycrystalline semiconductor film are processed into a tapered shape, and hence there is the following problem. When a mask using a resist is to be produced, namely, the space between patterns of a polycrystalline semiconductor film must be previously sized in anticipation of the resist withdrawal amount. Therefore, the process is disadvantageous in miniaturization and high resolution. This problem is more serious in the case where portions where a tapered shape is necessary, and those where a tapered shape is unnecessary in order to put priority on miniaturization mixedly exist. Therefore, the followings have been required. Namely, the dielectric strength of a gate insulating film is improved to obtain a highly reliable thin film transistor, and the layout areas of patterns are reduced to miniaturize the thin film transistor, thereby obtaining a high-resolution display device.

The invention is characterized in that tapered shapes of pattern end portions of a polycrystalline semiconductor film in the thin film transistor of the invention have at least two kinds of taper angles, and a portion where a tapering process is required has the smallest taper angle. Specifically, the invention is characterized in that the taper angle of the polycrystalline semiconductor film in a region where the polycrystalline semiconductor film intersects with a gate electrode is formed to be smaller than a taper angle in another region.

According to the thin film transistor of the invention, at least in a region where a polycrystalline semiconductor film intersects with a gate electrode, a pattern end portion of the polycrystalline semiconductor film has a small taper angle. Therefore, the covering property of a gate insulating film formed on the surface of the portion is sufficiently ensured. In a region where the polycrystalline semiconductor film does not intersect with a gate electrode, the tapered shape due to resist withdrawal is suppressed. Therefore, the layout area of the polycrystalline semiconductor film can be reduced. Consequently, effects that the dielectric strength of a gate insulating film of a thin film transistor is improved to enhance there liability of the thin film transistor, and that the layout area is reduced to miniaturize the thin film transistor, thereby obtaining a high-resolution display device. The invention can be applied not only to a liquid crystal display device, but also to an active matrix display device such as an EL display device.

### BRIEF DESCRIPTION OF THE DRAWINGS

Illustrative aspects of the invention will be described in detail with reference to the following figures wherein:

FIG. 1 is a plan view showing the configuration of a TFT substrate in Embodiment 1;

FIG. 2 is a plan view of a TFT of Embodiment 1;

FIG. 3 is a sectional view of the TFT of Embodiment 1;

FIG. 4 is a step sectional view showing an exposing process in a first photoetching in the TFT of Embodiment 1;

FIG. 5 is a step sectional view showing a state after a developing process in the first photoetching process in the TFT of Embodiment 1;

FIG. 6 is a step sectional view showing a state after a first etching process in the TFT of Embodiment 1;

FIG. 7 is a step sectional view showing a state after an ion doping process in the TFT of Embodiment 1;

FIG. 8 is a sectional view showing a state after a process of opening contact holes in the TFT of Embodiment 1;

FIG. 9 is a step sectional view showing a state after a process of forming a pixel electrode which is to be connected to the TFT of Embodiment 1; and

FIG. 10 is a graph showing relationships between a taper angle of a polycrystalline semiconductor film in the TFT of Embodiment 1, and the dielectric strength.

### DETAILED DESCRIPTION OF THE PREFERRED EMBODIMENT

### Embodiment 1

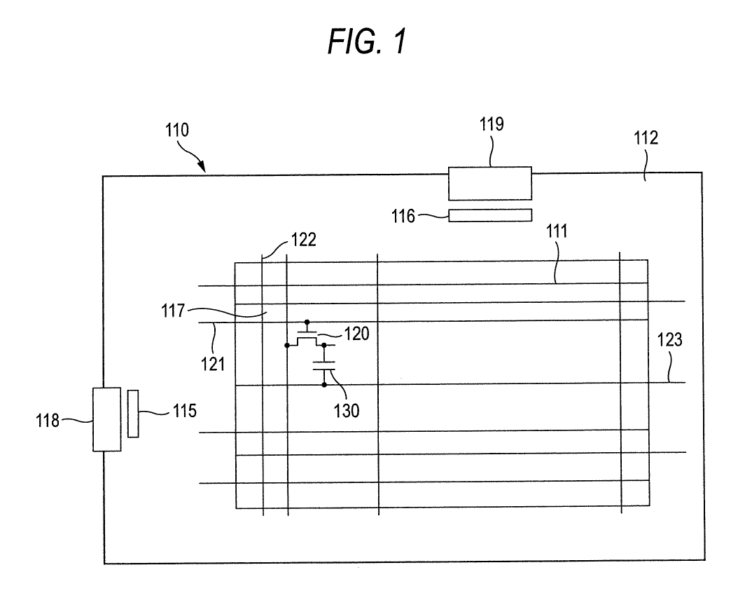

First, an active matrix display device to which a TFT substrate of the invention is applied will be described with reference to FIG. 1. FIG. 1 is a front view showing the configuration of a TFT substrate used in the display device. As the display device of the invention, a liquid crystal display device will be exemplarily described. However, this is for illustrative purpose only. Alternatively, for example, a flat panel display device such as an organic EL display device may be used.

The display device of the invention has the TFT substrate 110. For example, the TFT substrate 110 is a TFT array substrate. In the TFT substrate 110, a display region 111, and a frame region 112 which surrounds the display region 111 are disposed. In the display region 111, plural gate wirings (scan signal lines) 121 and plural source wirings (display signal lines) 122 are formed. The gate wirings 121 are disposed in parallel to one another. Similarly, the source wirings 122 are disposed in parallel to one another. The gate wirings 121 and the source wirings 122 are formed so as to intersect with one another. The gate wirings 121 and the source wirings 122 are orthogonal to one another. A region surrounded by gate and source wiring 121, 122 which are adjacent to each other functions as a pixel 117. In the TFT substrate 110, therefore, the pixels 117 are arranged in a matrix form. Storage capacity wirings 123 which cross the pixels 117 are formed in parallel to the gate wirings 121.

Moreover, a scan signal driving circuit 115 and a display signal driving circuit 116 are disposed in the frame region 112 of the TFT substrate 110. The gate wirings 121 are extended from the display region 111 to the frame region 112. In an end portion of the TFT substrate 110, the gate wirings 121 are connected to the scan signal driving circuit 115. Similarly, the source wirings 122 are extended from the display region 111 to the frame region 112. In an end portion of the TFT substrate 110, the source wirings 122 are connected to the display signal driving circuit 116. External wirings 118 are connected to the vicinity of the scan signal driving circuit 115, and external wirings 119 are connected to the vicinity of the display signal driving circuit 116. For example, the external wirings 118, 119 are configured by wiring substrates such as FPCs (Flexible Printed Circuits).

Various external signals are supplied to the scan signal driving circuit 115 and the display signal driving circuit 116 via the external wirings 118, 119. Based on an external control signal, the scan signal driving circuit 115 supplies a gate signal (scan signal) to the gate wirings 121. In response to the gate signal, the gate wirings 121 are sequentially selected. Based on an external control signal and display data, the display signal driving circuit 116 supplies a display signal to the source wirings 122. As a result, display voltages corresponding to the display data can be supplied to the pixels 117, respectively.

In each pixel 117, at least one TFT 120, and a storage capacitance element 130 which is connected to the TFT 120 are formed. The TFT 120 is placed in the vicinity of the intersection of the source wiring 122 and the gate wiring 121. For example, the TFT 120 supplies the display voltage to the pixel electrode. In response to the gate signal supplied through the gate wiring 121, namely, the TFT 120 which is a switching element is turned on. This causes the display voltage to be applied from the source wiring 122 to the pixel electrode connected to the drain electrode of the TFT. An electric field corresponding to the display voltage is produced between the pixel electrode and the opposing electrode. The storage capacitance element 130 is electrically connected not only to the TFT 120, but also to the opposing electrode via the storage capacity wiring 123. Therefore, the storage capacitance element 130 is connected in parallel to the capacity between the pixel electrode and the opposing electrode. An orientation film (not shown) is formed on the surface of the TFT substrate 110.

An opposing substrate is opposed to the TFT substrate 110. For example, the opposing substrate is a color filter substrate, and placed on the viewing side. A color filter, a black matrix (BM), the opposing electrode, an orientation film, and the like are formed on the opposing substrate. Sometimes, the opposing electrode may be placed on the side of the TFT substrate 110. A liquid crystal layer is interposed between the TFT substrate 110 and the opposing substrate. Namely, a liquid crystal exists between the TFT substrate 110 and the opposing substrate. A polarization plate, a phase difference plate, and the like are disposed on the outside faces of the TFT substrate 110 and the opposing substrate. A backlight unit or the like is disposed on the opposite viewing side of the liquid crystal display panel.

By the electric field between the pixel electrode and the opposing electrode, the liquid crystal is driven, i.e., the orientation direction of the liquid crystal between the substrates is changed. As a result, the polarization state of light passing through the liquid crystal layer is changed. Namely, the polarization state of light which passes through the polarization plate to be linearly polarized is changed by the liquid crystal layer. Specifically, light from the backlight unit is converted to linearly polarized light by the polarization plate on the side of the array substrate. When the linearly polarized light passes through the liquid crystal layer, the polarization state of the light is changed.

In accordance with the polarization state, the amount of light, which passes through the polarization plate on the side of the opposing substrate, is changed. Namely, among the transmitted light that is transmitted from the backlight unit through the liquid crystal display panel, the amount of light which passes through the polarization plate on the viewing side is changed in amount. The orientation direction of the liquid crystal is changed by the applied display voltage. By controlling the display voltage, therefore, the amount of light which passes through the polarization plate on the viewing side can be changed. When the display voltages for the respective pixels are varied, it is possible to display a desired image. In the series of operations, an electric field which is parallel to the electric field between the pixel electrode and the opposing substrate is formed in the storage capacitance element 130, thereby contributing to holding of the display voltage.

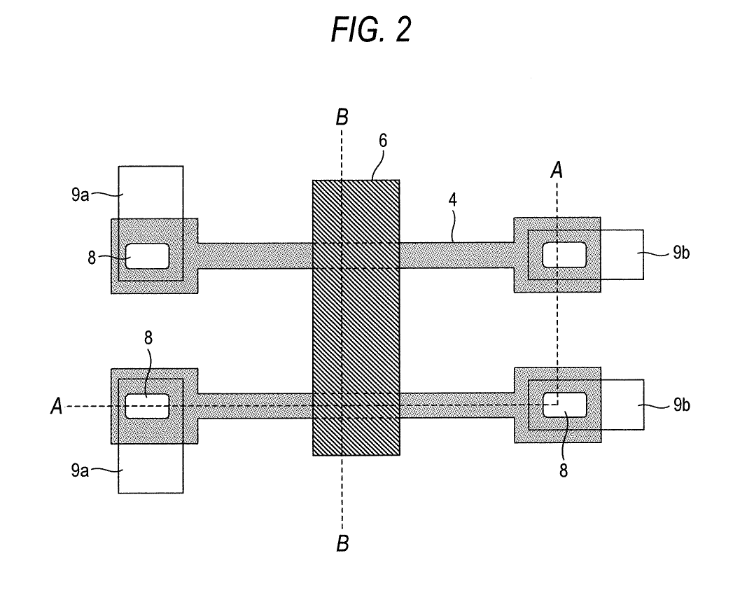

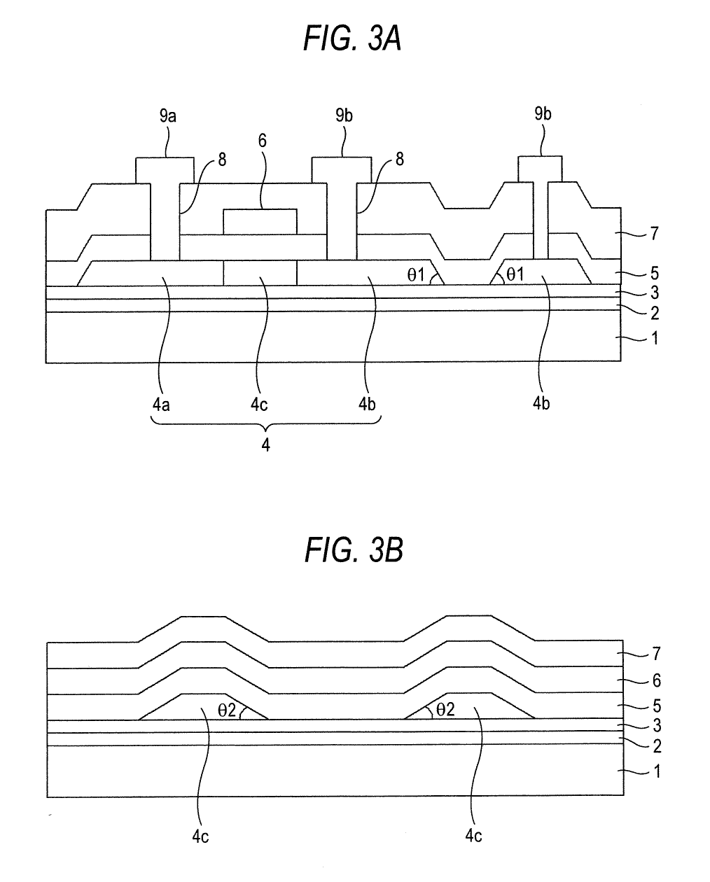

Next, the configurations of the TFT 120 which is disposed on the TFT substrate 110 will be described with reference to FIGS. 2, 3A, and 3B. FIG. 2 is a plan view of the TFT 120, FIG. 3A is a sectional view of a portion indicated by A-A in FIG. 2, and FIG. 3B is a sectional view of a portion indicated by B-B in FIG. 2. Hereinafter, the embodiment of the invention will be described with reference to FIGS. 2, 3A, and 3B. A polycrystalline semiconductor film 4 configured by polysilicon and the like is formed as a first conductive layer on a SiN film 2 and an SiO₂ film 3 on a glass substrate 1. The polycrystalline semiconductor film 4 is divided into a source region 4a, a channel region 4c, and a drain region 4b. Impurities are introduced in the source region 4a and the drain region 4b, so that the regions are lower in resistance than the channel region 4c. Pattern end portions of the polycrystalline semiconductor film 4 are processed so that their sections have a tapered shape. As a taper angle, two kinds of angles, i.e., θ1 of FIG. 3A and θ2 of FIG. 3B are indicated. An effect due to the difference between the taper angles will be described later.

A gate insulating film 5 which is an insulating film made of SiO₂ is formed so as to cover the polycrystalline semiconductor film 4 and the SiO₂ film 3, and a gate electrode 6 which is a second conductive layer is formed on the gate insulating film 5. The gate electrode 6 which is the second conductive layer is placed so as to have a region which intersects with the polycrystalline semiconductor film 4 via the gate insulating film 5 that is an insulating film formed on the polycrystalline semiconductor film 4 which is the first conductive layer. In the intersecting region, as seen also from FIG. 3A, the gate electrode 6 is opposed to the channel region 4c via the gate insulating film 5. Contact holes 8 are opened in the gate insulating film 5, and an interlayer insulating film 7 which is formed so as to cover the gate electrode 6. A source electrode 9a and drain electrode 9b which are on the interlayer insulating film 7 are connected to the source region 4a and the drain region 4b through the contact holes 8, respectively. Although not illustrated, the source electrode 9a or the drain electrode 9b is connected to a pixel electrode, and a voltage is applied to an electrooptic material such as a liquid crystal or a self-luminous material, thereby performing a display.

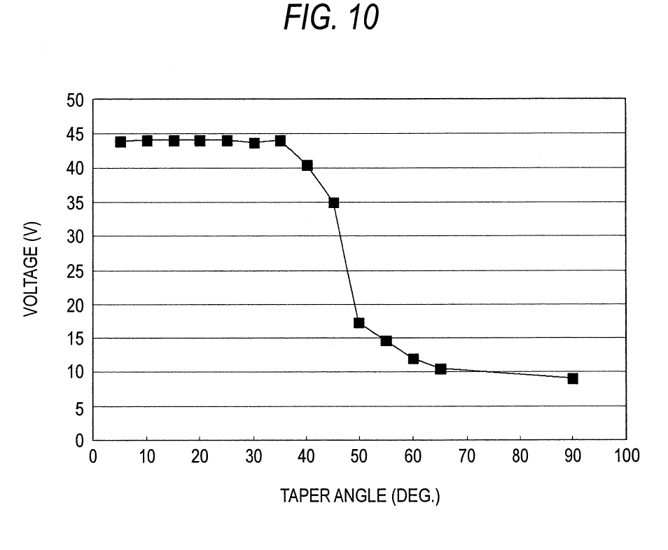

As taper angles of pattern ends of the polycrystalline semiconductor film 4, as seen form FIGS. 3A and 3B which are sectional views, there are the taper angle θ2 in a region which intersects with the gate electrode 6, and the taper angle θ1 in a region which does not intersect with the gate electrode 6, and which is opposed to the adjacent polycrystalline semiconductor film 4. The embodiment of the invention is characterized in that θ2 is smaller than θ1. In pattern ends of the polycrystalline semiconductor film 4, therefore, the gate electrode 6 having a high covering property is formed. Consequently, a failure such as a dielectric breakdown which may occur between the gate electrode 6 and the polycrystalline semiconductor film 4 can be sufficiently suppressed. FIG. 10 shows relationships between the taper angle and the dielectric strength of the gate insulating film 5. From FIG. 10, it will be seen that, in a range where the taper angle is equal to or smaller than 50°, the dielectric strength is further improved as the taper angle is more reduced. From the viewpoint of the dielectric strength, the lower limit of the taper angle is not observed. In the case where the taper angle is smaller than 20°, actually, a so-called hump characteristic appears in the TFT characteristic. Therefore, this case is not preferable. Consequently, the taper angle is preferably in a range of 20° or more to 50° or less. In a region which does not intersect with the gate electrode 6, and in which therefore it is not necessary to consider the above-mentioned dielectric breakdown, such as a region between adjacent portions of the polycrystalline semiconductor film 4, a small taper angle is not required, and hence the resist withdrawal amount in the process of patterning the polycrystalline semiconductor film 4 can be suppressed. Therefore, this can contribute to the reduction of the layout area, and the miniaturization of the thin film transistor.

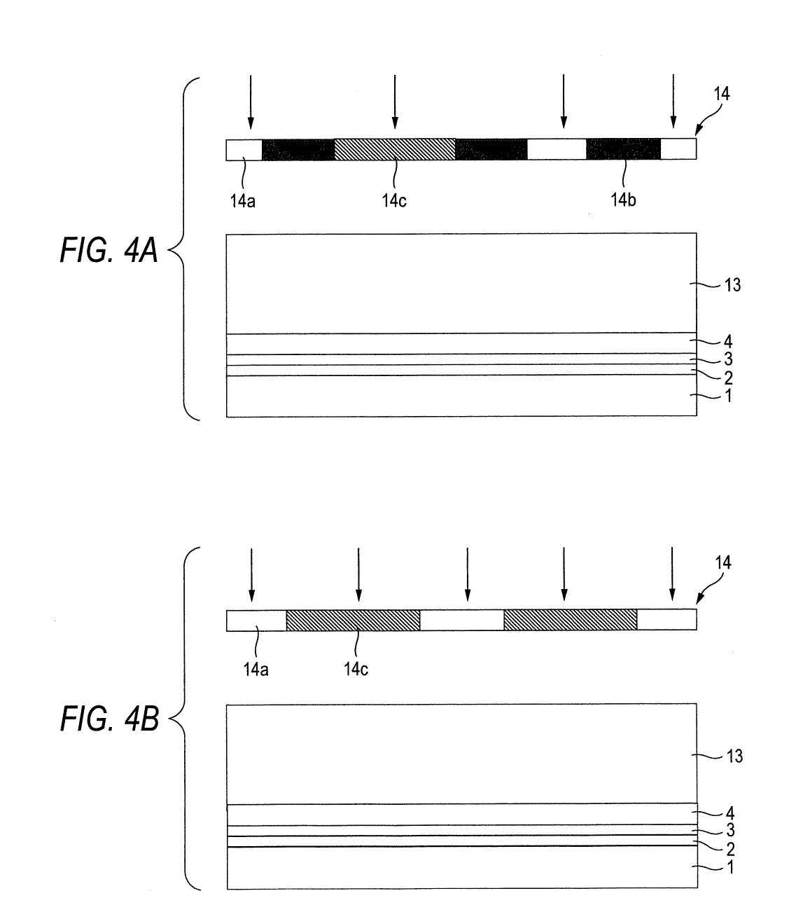

A method of producing the TFT substrate in the embodiment will be described with reference to FIGS. 4 to 8. FIGS. 4 to 8 are step sectional views showing process steps with respect to the sectional views of FIGS. 3A and 3B. For example, FIG. 4A corresponds to the step sectional view of FIG. 3A, and FIG. 4B corresponds to the step sectional view of FIG. 3B. Referring to FIGS. 4A and 4B, first, the SiN film 2 and SiO₂ film 3 which are light transmitting insulating films are formed as foundation films for the polycrystalline semiconductor film 4 by the CVD method on the glass substrate 1 which is an insulative substrate having a high light transmittance, such as a glass substrate or a quartz substrate. In the embodiment, a stacked layer structure is used in which an SiN film is formed in the thickness of 40 to 60 nm on a glass substrate, and an SiO₂ film is further grown in the thickness of 180 to 220 nm. The foundation films are disposed in order to prevent mobile ions which are caused mainly from the glass substrate 1, such as Na from diffusing into the polycrystalline semiconductor film 4. The film configuration and the film thickness are not restricted to the above-mentioned ones.

An amorphous semiconductor film is formed on the foundation films by the CVD method. In the embodiment, a silicon film is used as the amorphous semiconductor film. The silicon film is grown into a thickness of 30 to 100 nm, preferably 40 to 80 nm. Preferably, the foundation films and the amorphous semiconductor film are continuously grown in the same apparatus or the same chamber. According to the configuration, contaminants existing in the air atmosphere such as boron can be prevented from being captured in the interfaces of the films. Preferably, an annealing process is performed at a high temperature after the growth of the amorphous semiconductor film. This is conducted in order to reduce hydrogen which is contained in a large amount in the amorphous semiconductor film grown by the CVD method. In the embodiment, the interior of a chamber which was maintained to a low vacuum state in a nitrogen atmosphere was heated to about 480° C., and the substrate on which the amorphous semiconductor film was formed was held for 45 minutes. According to this process, even when the temperature is raised in crystallization of the amorphous semiconductor film, radical desorption of hydrogen does not occur, and surface roughness which may be caused after crystallization of the amorphous semiconductor film can be suppressed.

Then, a native oxide film formed on the surface of the amorphous semiconductor film is etched away by buffered hydrofluoric acid or the like. Next, while blowing a gas such as nitrogen against the amorphous semiconductor film, the amorphous semiconductor film is irradiated with a laser beam from the upper side. The laser beam passes through a predetermined optical system to be converted to a linear beam, and then irradiates the amorphous semiconductor film. In the embodiment, the second harmonic (oscillation wavelength: 532 nm) of a YAG laser was used as the laser beam. Alternatively, an excimer laser may be used in place of the second harmonic of a YAG laser. The height of bulges which are produced in the crystal grain boundary can be suppressed by irradiating the amorphous semiconductor film with the laser beam while blowing nitrogen. In the embodiment, the average roughness of the crystal surface is reduced to 3 nm or less. A TFT is formed by using the thus formed polycrystalline semiconductor film 4. In the polycrystalline semiconductor film 4, there is a conductive region which contains impurities introduced in an ion doping step that will be described later. The region constitutes the source region 4a and the drain region 4b. The region sandwiched by the source and drain regions 4a, 4b functions as the channel region 4c.

Next, a positive resist 13 which is a photosensitive resin was applied by the spin coat method onto the polycrystalline semiconductor film 4, and the applied resist 13 was subjected to exposing and developing processes. FIGS. 4A and 4B show this state. In the exposing process, a photomask 14 such as shown in FIGS. 4A and 4B was used. The photomask 14 includes: a transmissive portion 14a through which light from an exposure light source can be transmitted; a light blocking portion 14b which blocks light; and a semi-transmissive portion 14c in which the transmittance for the light from the light source is lower than that of the transmissive portion 14a, and higher than that of the light blocking portion 14b. FIG. 4A shows the exposure state which is obtained after the application of the resist 13. The placement of the semi-transmissive portion 14c corresponds to a position where the portion includes the region which intersects with the gate electrode 6 in FIG. 2. The placement of the light blocking portion 14b corresponds to positions where the portion includes regions in which the contact holes 8 are formed in FIG. 2. The placement of the transmissive portion 14a corresponds to the region in which the polycrystalline semiconductor film 4 is not formed in FIG. 2. FIG. 4B shows the region which intersects with the gate electrode 6, and hence the semi-transmissive portion 14c is formed also in the photomask 14 in a similar manner as described above. By contrast, the transmissive portion 14a is formed so as to correspond to the region in which the polycrystalline semiconductor film 4 is not formed. These placements in the photomask 14 are predetermined so to match with the pattern of the polycrystalline semiconductor film 4 formed on the glass substrate 1.

In the exposing process shown in FIGS. 4A and 4B, in the region in which exposure is performed through the semi-transmissive portion 14c, an influence due to diffracted light of the illumination light or the like occurs, and hence the amount of illumination light in the vicinity of the region is stepwisely changed. The positive resist which was used in the embodiment has the property that, as the illumination light amount is larger, the thickness of the resist remaining after the developing process is smaller. Therefore, also the end shape of the resist 13 after the developing process is correspondingly stepwisely changed, with the result that a tapered shape is obtained also in the end portion of the resist after the developing process. The photomask 14 used in the embodiment comprises the semi-transmissive portion 14c that reduces the light amount to an exposure amount at which the thickness of the resist in the region intersecting with the gate electrode 6 is 700 nm.

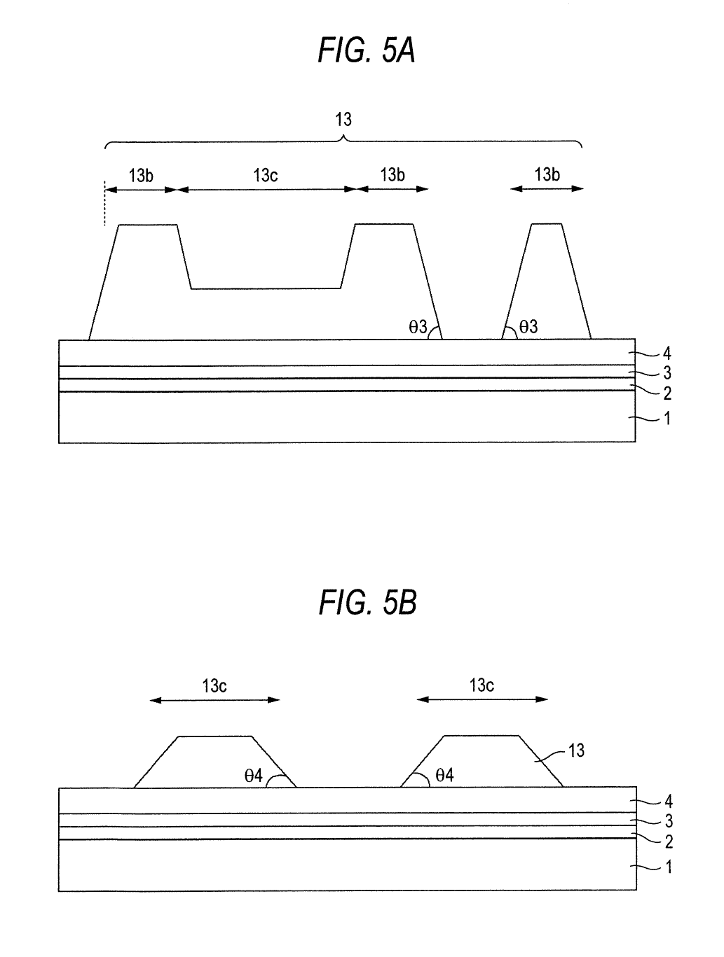

FIGS. 5A and 5B show a state in which, after the exposing process shown in FIGS. 4A and 4B, an developing process is performed by using an alkali developer. In the resist 13 shown in FIGS. 5A and 5B, regions corresponding to the light blocking portion 14b and semi-transmissive portion 14c of the photomask 14 are indicated as a resist 13b and a resist 13c, respectively. In the region corresponding to the transmissive portion 14a, the resist is illuminated with a sufficient light amount, and hence the resist 13 is removed away and does not remain after the developing process. Therefore, the region is not particularly indicated. In the case of a negative resist, by contrast, the resist of the region corresponding to the light blocking portion 14b is removed away and does not remain. The taper angle of the region corresponding to the boundary between the transmissive portion 14a and the light blocking portion 14b shown in FIG. 4A is indicated by θ3 in FIG. 5A. Similarly, the taper angle of the region corresponding to the boundary between the transmissive portion 14a and the semi-transmissive portion 14c shown in FIG. 4B is indicated by θ4 in FIG. 5B.

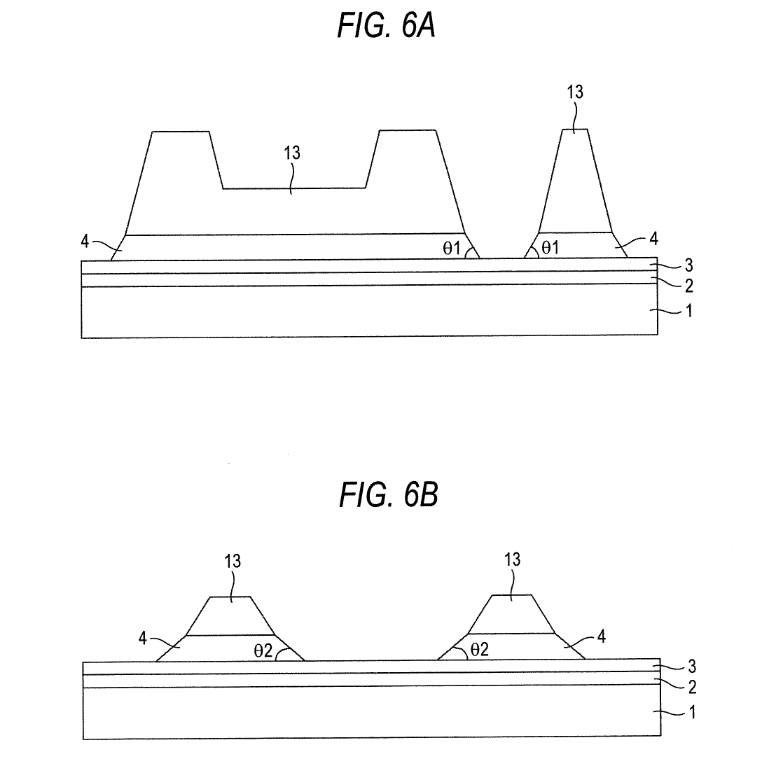

The resist 13b and the resist 13c will be compared with each other. With respect to the thickness of the resist remaining after the developing process, the resist 13c is thinner than the resist 13b because the light transmittance of the semi-transmissive portion 14c is higher than that of the light blocking portion 14b. As described above, in the vicinity of the semi-transmissive portion 14c, the amount of the transmitted light is stepwisely changed. As shown in FIG. 6B, therefore, the taper angle is reduced, with the result that θ4 is smaller than θ3. In the embodiment, a value of 70 to 80° was obtained as θ3, and that of 30 to 40° was obtained as θ4. The thickness of the resist 13c was 700 nm, and that of the resist 13b was 1.5 μm. In the embodiment, while using the thus formed resist 13 as a mask, the polycrystalline semiconductor film was processed by a dry etching method using a mixture gas of CF₄ and O₂.

FIGS. 6A and 6B show a state in which the polycrystalline semiconductor film 4 is etched from the state of FIGS. 5A and 5B. As the dry etching method in the embodiment, an etching method was used in which a resist is withdrawn by an anisotropic etching having an excellent controllability of the shape process. In such an etching, the magnitude relationship between the taper angles θ3 and θ4 of the resist 13 which has been described above is basically reflected to that of the taper angles of the polycrystalline semiconductor film 4, and hence it was possible to obtain the polycrystalline semiconductor film 4 in which the taper angle θ2 of the polycrystalline semiconductor film 4 of the region intersecting with the gate electrode 6 is smaller than the taper angle θ1 of the other region. According to the configuration, in the region intersecting with the gate electrode 6, a shape of a small taper angle which is advantageous to the covering property is obtained. By contrast, in the regions indicated by θ3 in FIG. 5A, the resist withdrawal amount in the etching process using the resist withdrawal method can be suppressed, and hence the distance between adjacent TFTs can be shortened, thereby contributing to a high resolution. In the embodiment, it was possible to obtain a shape in which the region intersecting with the gate electrode 6 has a taper angle of 25° and the other region has a taper angle of about 70°. After the etching process in FIGS. 6A and 6B is completed, the resist 13 is removed away by a known method.

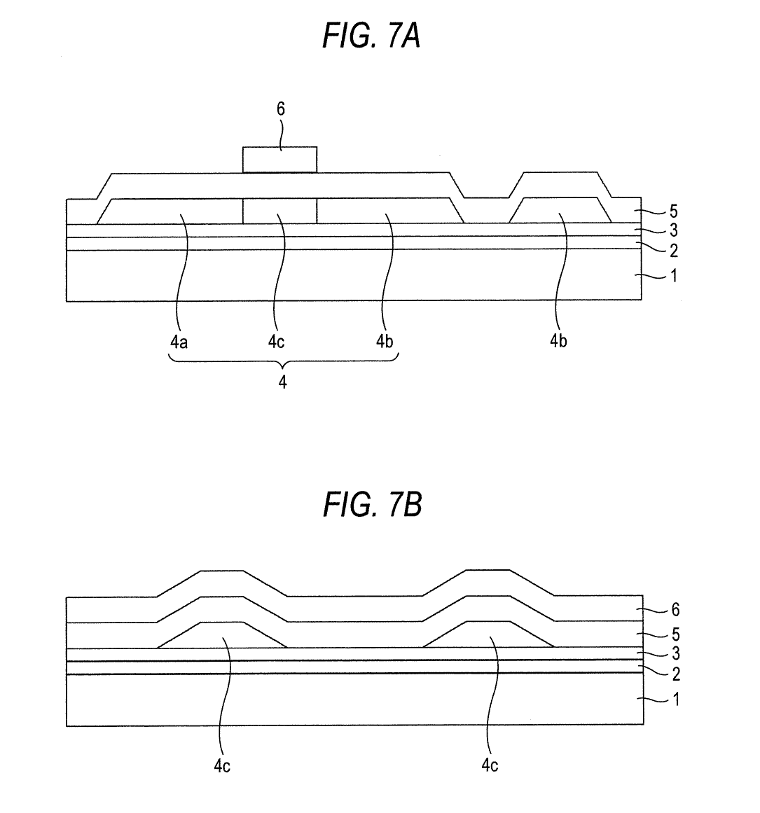

Next, referring to FIGS. 7A and 7B which are step sectional views of the TFT of the embodiment, the gate insulating film 5 is formed so as to cover the whole surface of the substrate. Namely, the gate insulating film 5 is grown on the polycrystalline semiconductor film 4. A SiN film or an SiO₂ film is used as the gate insulating film 5. In the embodiment, a SiO₂ film is used as the gate insulating film 5, and grown to a thickness of 80 to 100 nm by the CVD method. The surface roughness of the polycrystalline semiconductor film 4 is set to 3 nm or less, and an end portion of a pattern intersecting with the gate electrode 6 is formed into a tapered shape. Therefore, the gate insulating film 5 has a high covering property, and initial failures can be largely reduced.

Furthermore, a conductive film for forming the gate electrode 6 and the wiring is grown, and then patterned by using a known photoetching process to a desired shape, thereby forming the gate electrode 6, and the wirings (not shown). In the embodiment, a Mo film was grown to a thickness of 200 to 400 nm by a sputtering method using a DC magnetron. The etching process on the conductive film was performed by a wet etching method using a chemical solution in which nitric and phosphoric acids are mixed with each other. In the embodiment, a Mo film was used as the conductive film. Alternatively, Cr, W, or Ta, or an alloy film essentially containing such a metal may be used.

Next, impurities are introduced into the polycrystalline semiconductor film 4 via the gate insulating film 5 with using the formed gate electrode 6 as a mask. As the impurity element to be introduced, P or B may be used. When P is introduced, an n-type TFT can be formed. Although not shown, when the process on the gate electrode 6 is dividedly performed in two steps, or a step of forming a gate electrode for an n-type TFT, and that of forming a gate electrode for a p-type TFT, n- and p-type TFTs can be produced. The introduction of the impurity element of P or B was performed by using the ion doping method. As a result to the above steps, as shown in FIG. 7A, the source region 4a and the drain region 4b are formed, and at the same time the channel region 4c which is masked by the gate electrode 6, and into which the impurities are not introduced is formed.

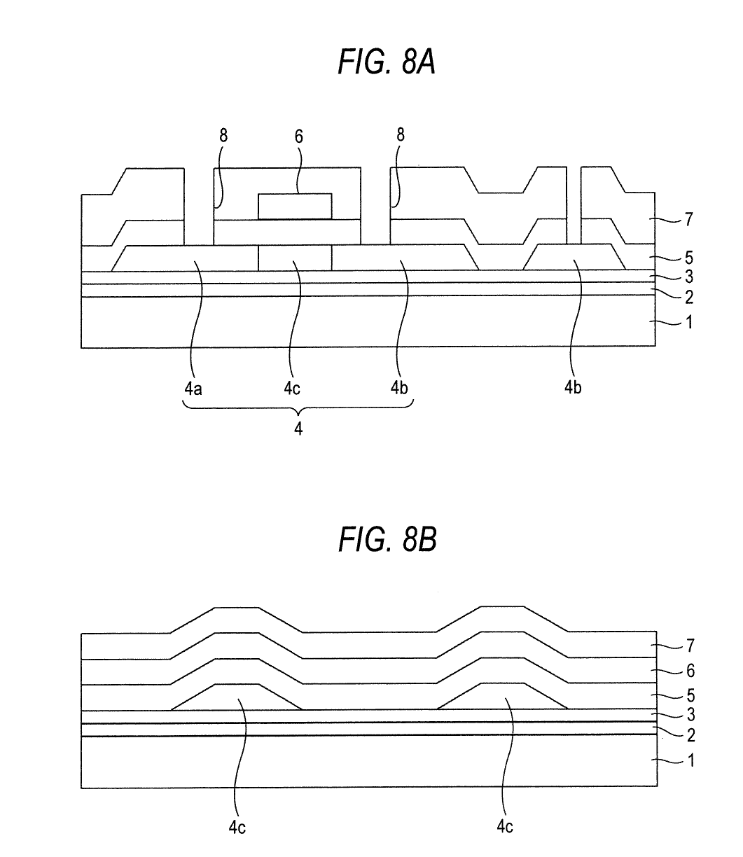

Next, referring to FIGS. 8A and 8B which are step sectional views of the TFT of the embodiment, the interlayer insulating film 7 is grown so as to cover the whole surface of the substrate. Namely, the interlayer insulating film 7 is grown on the gate electrode 6. In the embodiment, an SiO₂ film having a thickness of 500 to 700 nm was grown by the CVD method to be formed as the interlayer insulating film 7. Then, the resulting article was held for about one hour in an annealing oven which was heated to 450° C. in a nitrogen atmosphere. This is performed in order to activate the impurity elements introduced into the source and drain regions 4a, 4b of the polycrystalline semiconductor film 4.

Then, the gate insulating film 5 and interlayer insulating film 7 which are formed are patterned to a desired shape by using a known photoetching process. In this process, the contact holes 8 which respectively reach the source and drain regions 4a, 4b of the polycrystalline semiconductor film 4 are formed. Namely, in the contact holes 8, the gate insulating film 5 and the interlayer insulating film 7 are removed away, and the source and drain regions 4a, 4b of the polycrystalline semiconductor film 4 are exposed. In the embodiment, the etching of the contact holes 8 was performed by the dry etching method using a mixture gas of CHF₃, O₂, and Ar.

Next, referring to FIG. 3A which is a sectional view of the TFT of the embodiment, the conductive film 9 is grown on the interlayer insulating film 7 so as to cover the contact holes 8, and patterned into a desired shape by using a known photoetching process to form the source electrode 9a, the drain electrode 9b, and a wiring (not shown). As the conductive film in the embodiment, a stacked structure of Mo/Al/Mo which is formed by continuously growing a Mo film, an Al film, and a Mo film by a sputtering method using a DC magnetron was used. The thickness of the Al film was 200 to 400 nm, and that of the Mo film was 50 to 150 nm. The etching of the conductive film was performed by a dry etching method using a mixture gas of SF₆ and O₂ and a mixture gas of Cl₂ and Ar. As a result of the above steps, as shown in FIGS. 2 and 3A, the source electrode 9a connected to the polycrystalline semiconductor film 4 is formed on the source region 4a, and the drain electrode 9b connected to the polycrystalline semiconductor film 4 is formed on the drain region 4b. After the series of steps, the TFT can be formed.

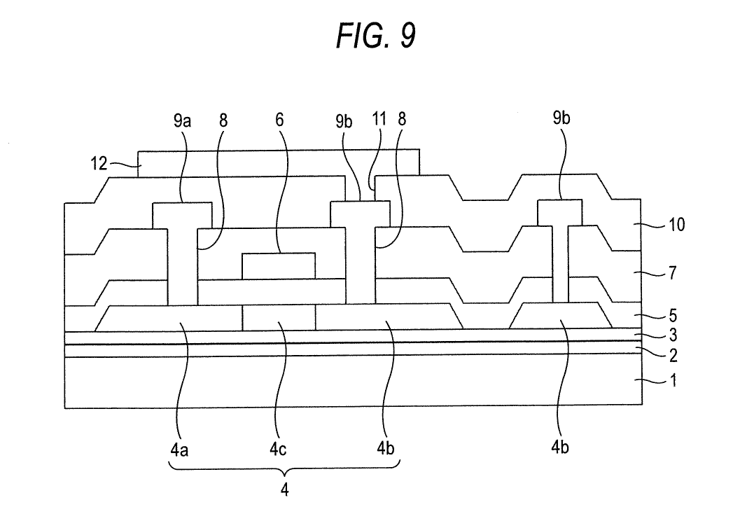

When the thus formed TFT is to be applied to an active matrix display device, a pixel electrode is added to the drain electrode 9b. Hereinafter, description will be made with reference to FIG. 9 that is a sectional view showing a status in which a pixel electrode is further formed in FIG. 3A. First, the second interlayer insulating film 10 is grown so as to cover the whole surface of the substrate. Namely, the second interlayer insulating film 10 is grown on the source electrode 9a and the drain electrode 9b. Thereafter, the second contact hole 11 which reaches the drain electrode 9b is opened in the second interlayer insulating film 10 by using a known photoetching process. In the embodiment, a SiN film having a thickness of 200 to 300 nm was grown by the CVD method to be formed as the second interlayer insulating film 10. The process of opening the second contact hole 11 was performed by a dry etching method using a mixture gas of CF₄ and O₂.

Next, a conductive film of a transparent material such as ITO or IZO is grown, and then patterned into a desired shape by using a known photoetching process, thereby forming the pixel electrode 12 which is connected to the drain electrode 9b through the contact hole 11. In the embodiment, a transparent amorphous conductive film having an excellent workability was grown as the conductive film by a sputtering method using a DC magnetron and a mixture gas of an Ar gas, an O₂ gas, and an H₂O gas. The etching of the conductive film was performed by a wet etching method using a chemical solution essentially containing oxalic acid.

Then, an unwanted resist is removed away, and thereafter an annealing process is performed, whereby the pixel electrode 12 configured by a transparent amorphous conductive film is crystallized to complete the TFT substrate 110 which is to be used in the display device. When the thus completed TFT substrate 110 is used, a high-resolution display device can be obtained in which a display failure due to a dielectric breakdown between the polycrystalline semiconductor film and the gate electrode does not occur, and which has an excellent layout property.

In the polycrystalline semiconductor film 4 of the thin film transistor of the embodiment, the taper angle of the region intersecting with the gate electrode 6 is smaller than that of the vicinity of the regions of the contact holes 8. Conversely, the taper angle of the region intersecting with the gate electrode 6 may be larger than that of the vicinity of the regions of the contact holes 8.

In the embodiment, the polycrystalline semiconductor film pattern having both a small taper angle for improving the covering property in the case of an intersection with the gate electrode, and an a large taper angle for allowing elements such as thin film transistors to be arranged in a high density, and the method forming the pattern have been described. Even when the object or the effect is different, the embodiment can be similarly applied to any case where different taper angles are to be optimized in the same pattern.

In the embodiment, the polycrystalline semiconductor film which has different taper angles in the same pattern has been described. The embodiment can be applied to the case of plural discrete patterns. Namely, when a resist pattern is formed for each pattern to be formed, the resist pattern may be formed so that the resist thickness of a pattern in which the taper angle is to be small is reduced.

When discrete patterns are usually formed by using a resist, it is known that the taper angle of a resist end portion is affected by the size of each pattern. In the case where the size of a pattern is less than several times the thickness of the pattern, particularly, the volume itself of the pattern is small, and it is sometimes difficult to form a small taper angle. By contrast, in the embodiment, the resist thickness can be reduced locally or only in a portion where the taper angle is to be reduced, whereby the above-mentioned volume effect of a resist can be lessened. Therefore, a small taper angle can be formed even in a small-width pattern region such as the intersection with the gate electrode 6. This is applicable also to the case of discrete patterns. Conversely, in the case where a large taper angle is necessary, it is not required to reduce the thickness of a resist as described in the embodiment.

The case where the embodiment is applied to a polycrystalline semiconductor film of an LTPS-TFT of the top-gate type has been described. The invention is not restricted to this, and, if there is a similar problem, the embodiment can be applied also to a thin film transistor of the inverse staggered type, or a thin film transistor using an amorphous semiconductor film. In a known TFT of the inverse staggered type, when a similar problem occurs in a source wiring, drain electrode, and pixel electrode which are formed above an amorphous semiconductor film, for example, the invention can be applied. Furthermore, the invention can be applied not only to a thin film transistor, but also to an electronic device which has region where first and second conductive layers intersect with each other via an insulating film, and in which the first conductive layer is requested to have at least two kinds of taper angles.

In the embodiment, changes of types in which the effects of the invention are impaired may be conducted. For example, the case where, when the resist 13 on the polycrystalline semiconductor film 4 is exposed, the photomask 14 having the transmissive portion 14a, the light blocking portion 14b, and the semi-transmissive portion 14c is used has been described. Alternatively, an exposing process using a first photomask in which the transmissive portion 14a and the light blocking portion 14b are formed, and another exposing process using a second photomask in which the semi-transmissive portion 14c and the light blocking portion 14b are formed may be separately performed. In the alternative, the light blocking portion 14b of the first photomask must include a region corresponding to the semi-transmissive portion 14c of the second photomask. In summary, it is requested that, while using a photomask including at least two kinds of the transmissive portion 14a, the semi-transmissive portion 14c, and the light blocking portion 14b, the resist 13 in a region where the gate electrode 6 intersects with the polycrystalline semiconductor film 4 is exposed by light which passes through the semi-transmissive portion 14c. In other words, in the case of a positive resist, it is requested that the amount of light which illuminates a region where the gate electrode 6 intersects with the polycrystalline semiconductor film 4 is larger than that of light which illuminates the polycrystalline semiconductor film 4 in the other region.

In the embodiment, the case where the two kinds of taper angles are used has been described. Alternatively, three or more kinds of taper angles may be used. When the resist 13 of the polycrystalline semiconductor film 4 is to be exposed, namely, the semi-transmissive portion 14c of the photomask 14 may have two or more kinds of transmittances. When desired portions have different transmittances, it is possible to form thicknesses of resists remaining after the developing process in multi-step manner, in addition to the amount of exposure light. Therefore, also the taper angle of the polycrystalline semiconductor film 4 can be formed in multi-step manner for respective desired portions.

What is claimed is:

1. A thin film transistor comprising:
a first conductive layer which is formed on an insulative substrate;
an insulating film which is formed on the first conductive layer; and
a second conductive layer which is formed on the insulating film, and which has a region intersecting with the first conductive layer via the insulating film,
wherein the first conductive layer has at least two kinds of taper angles.

2. A thin film transistor according to claim 1, wherein, in the first conductive layer, a taper angle of a region intersecting with the second conductive layer is smaller than a taper angle of a region other than the region intersecting with the second conductive layer.

3. A thin film transistor according to claim 1, wherein, in the first conductive layer, a taper angle of a region intersecting with the second conductive layer is from 20° to 50°.

4. A thin film transistor according to claim 1, wherein the first conductive layer is a polycrystalline semiconductor film, and the second conductive layer is a gate electrode.

5. A method of producing a thin film transistor, comprising the steps of:
forming a semiconductor layer on an insulative substrate;
forming a resist on the semiconductor layer;
performing an exposing process on the resist with using a photomask including at least two of a transmissive portion, a semi-transmissive portion, and a light blocking portion;
performing a developing process after the exposing process;
etching the semiconductor layer after the developing process,
removing the resist after the etching;
forming a gate insulating film to cover the semiconductor layer;
forming a gate electrode having a region which intersects with the semiconductor layer via the gate insulating film; and
forming source and drain electrodes which are connected to the semiconductor layer, wherein
with respect to a thickness of the resist remaining after the exposing process, a region where the semiconductor layer intersects with the gate electrode is thinner than another region.

6. A display device wherein the display device is formed by using a thin film transistor according to claim 1.
